(19) United States
(12) Patent Application Publication
(10) Pub. No.: US 2025/0204100 A1
(43) Pub. Date: Jun. 19, 2025

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: Qing WANG, Xiamen (CN); Ling-Yuan HONG, Xiamen (CN); Zhanggen XIA, Xiamen (CN); Peng LIU, Xiamen (CN); Minyou HE, Xiamen (CN); Xiaoliang LIU, Xiamen (CN); Chung-Ying CHANG, Xiamen (CN)

(21) Appl. No.: 19/062,304

(22) Filed: Feb. 25, 2025

Related U.S. Application Data
(63) Continuation of application No. PCT/CN2022/115783, filed on Aug. 30, 2022.

(51) Int. Cl. H10H 20/841; H10H 20/816; H10H 20/831; H10H 20/857

(52) U.S. Cl. CPC H10H 20/841; H10H 20/8162; H10H 20/831; H10H 20/857

(57) ABSTRACT

A light-emitting diode includes an epitaxial structure, a first metal electrode, a second metal electrode, an insulating stack layer, a metal reflective layer, a first connection electrode, and a second connection electrode. The epitaxial structure includes a first semiconductor layer, a light-emitting layer, and a second semiconductor layer sequentially arranged in that order along a direction from the lower surface to the upper surface. The first and second metal electrodes are located on the upper surface of the epitaxial structure. The insulating stack layer covers portions of the epitaxial structure and the contact electrode, and includes a first insulating layer and a second insulating layer located on the first insulating layer. The metal reflective layer is sandwiched between the first and second insulating layers. The first and second connection electrodes are located above the insulating stack layer and are connected to the first and second metal electrodes, respectively.

### TECHNICAL FIELD

The disclosure relates to the field of semiconductor manufacturing technologies, and particularly to a light-emitting diode and a light-emitting device.

### BACKGROUND

A light emitting diode (LED), is a kind of semiconductor light-emitting component, typically made from a semiconductor such as gallium nitride (GaN), gallium arsenide (GaAs), gallium phosphide (GaP), or gallium arsenide phosphide (GaAsP), and its core is a positive-negative (PN) junction with luminescent property. The LED is considered one of the most promising light sources due to its high luminous intensity, high efficiency, small size, and long service life. The LED has been widely used in lighting, monitoring and command, high-definition broadcasting, high-end cinemas, office displays, conference interaction, virtual reality and other fields.

A conventional flip-chip LED primarily uses a distributed bragg reflector (DBR) layer to reflect light emitted by a light-emitting layer, thereby enhancing a light-emitting performance of the LED chip. However, the DBR layer has poor reflection effects on light of certain specific wavelength ranges and cannot effectively reflect across a full spectrum of white light, leading to a weakened light-emitting performance of the LED chip. Particularly, a brightness the LED chip is not competitive in the field of plant lighting. Moreover, a reliability of the conventional LED chip is also relatively poor and requires further improvement.

Therefore, how to effectively enhance the light-emitting performance and reliability of the LED chip has become an urgent technical challenge for professionals in the field.

At present, some technologies have proposed adding an additional metal reflective layer on a top of the DBR layer. Since the metal reflective layer can effectively reflect light across the full spectrum, it can improve the reflection efficiency of the DBR layer. If the metal reflective layer is placed on a connection electrode or a pad electrode above the DBR layer, due to the pad electrode or the connection electrode having positive and negative polarities, there will be a large area of electrode gaps. Light that is transmitted through the DBR layer and reaches between these electrode gaps still cannot be effectively reflected. Additionally, since a first layer of the pad electrode or connection electrode is an adhesion layer, which serves to enhance the adhesion of the electrode to the DBR layer, even if the first layer is very thin, it can still cause some light absorption. Therefore, addition of the additional metal reflective layer on the DBR layer and covering the metal reflective layer with an insulating layer are proposed. The metal reflective layer can be set over a larger area, ensuring effective reflection of light that would otherwise reach the electrode gaps.

Currently, the commonly used metal reflective layer is an aluminum reflective layer and a silver reflection layer. Since aluminum and silver are quite unstable and prone to oxidation and corrosion, design improvements are needed to maintain a stability of the reflectivity, thereby ensuring a long-term high efficiency of the product's light output.

### SUMMARY

A light-emitting diode is provided, and the light-emitting diode includes an epitaxial structure, a first metal electrode, a second metal electrode, an insulating stack layer, a metal reflective layer, a first connection electrode, and a second connection electrode. The epitaxial structure includes a lower surface and an upper surface opposite to each other, and the epitaxial structure includes a first semiconductor layer, a light-emitting layer, and a second semiconductor layer sequentially arranged in that order along a direction from the lower surface to the upper surface, and a portion of an upper surface of the first semiconductor layer is uncovered by the light-emitting layer. The first metal electrode is disposed above the first semiconductor layer of the epitaxial structure and is electrically connected to the first semiconductor layer. The second metal electrode is disposed above the second semiconductor layer of the epitaxial structure and is electrically connected to the second semiconductor layer. The insulating stack layer is disposed covering a portion of the epitaxial structure, a portion of the first metal electrode, and a portion of the second metal electrode, the insulating stack layer includes a first insulating layer and a second insulating layer, and the second insulating layer is disposed above the first insulating layer. The metal reflective layer is sandwiched between the first insulating layer and the second insulating layer of the insulating stack layer. The first connection electrode is disposed above the insulating stack layer and is connected to the first metal electrode. The second connection electrode is disposed above the insulating stack layer and is connected to the second metal electrode. A vertical projection of at least one of the first metal electrode and the second metal electrode on a horizontal plane is non-overlapped with a vertical projection of the metal reflective layer on the horizontal plane.

In an embodiment, a vertical projection of at least one of a lower surface of the first metal electrode and a lower surface of the second metal electrode on the horizontal plane is non-overlapped with a vertical projection of a lower surface of the metal reflective layer on the horizontal plane.

In an embodiment, the metal reflective layer and the first insulating layer together form a reflective structure layer.

In an embodiment, the metal reflective layer is located above the upper surface of the epitaxial structure.

In an embodiment, the metal reflective layer is only located above the second semiconductor layer.

In an embodiment, a thickness of the metal reflective layer is in a range of 200 nanometers (nm) to 1000 nm, and a thickness of the second insulating layer is in a range of 200 nm to 1000 nm.

In an embodiment, a material of the metal reflective layer includes silver (Ag) and aluminum (Al).

In an embodiment, the second insulating layer is disposed covering an upper surface and inclined side walls of the metal reflective layer, and the first insulating layer is in direct contact with the second insulating layer at a periphery of the metal reflective layer.

In an embodiment, the first insulating layer is a distributed bragg reflector (DBR) formed by a repeated stacking of two types of insulating materials, and a thickness of the first insulating layer is in a range of 2 micrometers (μm) to 6 μm.

In an embodiment, the insulating stack layer includes a first opening and a second opening, the first opening is located above the first metal electrode, the first opening penetrates through the first insulating layer and the second insulating layer, the second opening is located above the second metal electrode, and the second opening penetrates through the first insulating layer and the second insulating layer. The metal reflective layer includes a third opening surrounding the second opening, and a width at a bottom of the third opening is greater than a width of the second opening at a contact position of the first insulating layer and the second insulating layer.

In an embodiment, the width at the bottom of the third opening is greater than a width dimension at a top of the second opening.

In an embodiment, the insulating stack layer includes a first opening and a second opening. The first opening is located above the first metal electrode, and the second opening is located above the second metal electrode. A top of the first opening is higher than the upper surface of the first metal electrode, and a top of the second opening is higher than the upper surface of the second metal electrode.

In an embodiment, the vertical projection of the metal reflective layer on the horizontal plane only falls within a range of the vertical projection of the second semiconductor layer on the horizontal plane.

In an embodiment, the light-emitting diode further includes an insulating structure, a first pad electrode, and a second pad electrode. The insulating structure is disposed covering a portion of the insulating stack layer, a portion of the first connection electrode, and a portion of the second connection electrode; the first pad electrode is located above the insulating structure and is connected to the first connection electrode; the second pad electrode is located above the insulating structure and is connected to the second connection electrode.

In an embodiment, the light-emitting diode further includes a current blocking layer, and the current blocking layer is disposed between the second semiconductor layer and the second metal electrode.

In an embodiment, the light-emitting diode further includes a transparent current spreading layer, and the transparent current spreading layer is disposed between the current blocking layer and the second metal electrode, and the transparent current spreading layer is arranged covering the current blocking layer.

In an embodiment, the vertical projection of the metal reflective layer on the horizontal plane is non-overlapped with a vertical projection of the current blocking layer on the horizontal plane.

In an embodiment, the vertical projection of the metal reflective layer on the horizontal plane is overlapped with both vertical projections of the first connection electrode and the second connection electrode on the horizontal plane.

In an embodiment, an edge of the metal reflective layer comprises inclined sidewalls, and inclination angles of the respective inclined sidewalls are less than or equal to 40°.

In an embodiment, each of the first metal electrode and the second metal electrode comprise a strip-shaped extension, and the strip-shaped extension extends in a direction of a connecting line of the first connection electrode with the second connection electrode.

In an embodiment, portions of the vertical projection of the metal reflective layer are arranged spaced from one another and just above the second semiconductor layer.

A light-emitting device utilizes the light-emitting diode mentioned above is provided. Generally, the light-emitting device includes a driving circuit board, and the light-emitting diode is disposed on and electrically connected to the driving circuit board.

The disclosure provides a light-emitting diode and a light-emitting device. By configuring the insulating stack layer and the metal reflective layer, the light emitted from the light-emitting layer is fully reflected, thereby enhancing the light-emitting performance of the light-emitting diode. By arranging at least one of the vertical projections of the first metal electrode and the second metal electrode on the horizontal plane being non-overlapped with the vertical projection of the metal reflective layer on the horizontal plane, a risk of the metal reflective layer being eroded by water vapor due to poor coverage of the insulating stack layer at a step position is reduced. This prevents a destruction of the reflective characteristics of the metal reflective layer or the creation of leakage current paths that could lead to chip failure, thus improving the reliability and light-emitting performance of the light-emitting diode.

Other features and advantages of the disclosure will be set forth in the following description and, in part, will be apparent from the description, or may be learned by practice of the disclosure.

### BRIEF DESCRIPTION OF DRAWINGS

In order to provide a clearer explanation of the embodiments of the disclosure or the technical solutions in the related art, a brief introduction will be given to the attached drawings required for the description of the embodiments or the prior art. It is apparent that the attached drawings described below are some embodiments of the disclosure. For those skilled in the art, other drawings can be obtained based on the attached drawings without creative labor.

FIG. 1 illustrates a schematic structural diagram of a light-emitting diode according to a first embodiment of the disclosure.

FIG. 2 illustrates a schematic diagram of vertical projection line segments of a metal reflective layer, a first metal electrode, and a second metal electrode illustrated in FIG. 1 on a horizontal plane.

FIG. 3 illustrates a schematic top view of the light-emitting diode according to the first embodiment of the disclosure.

FIG. 4 illustrates a schematic structural diagram of a light-emitting diode according to a second embodiment of the disclosure.

FIG. 5 illustrates a schematic structural diagram of a light-emitting diode according to a third embodiment of the disclosure.

FIG. 6 illustrates a schematic top view of the light-emitting diode according to another embodiment of the disclosure.

FIG. 7 illustrates a scanning electron microscope (SEM) image of a partial structure of a light-emitting diode according to still another embodiment of the disclosure.

### DESCRIPTION OF REFERENCE NUMERALS

1, 2, 3—light-emitting diode; 10—substrate; 12—epitaxial structure; 121—lower surface; 122—upper surface; 123—first semiconductor layer; 124—light-emitting layer; 125—second semiconductor layer; 21—first metal electrode; 211—strip-shaped extension; 22—second metal electrode; 221—strip-shaped extension; 26—metal reflective layer; 261—inclined sidewall; 262 inclination angle; 32—insulating stack layer; 321—first insulating layer; 322—second insulating layer; 34—insulating structure; 41—first connection electrode; 42—second connection electrode; 51—first pad electrode; 52—second pad electrode; 61—first opening; 62—second opening; 63—third opening; 64—current blocking layer; 66—transparent current spreading layer; L1, L3—minimum horizontal inner spacing; L2, L4, L5—maximum horizontal inner spacing.

### DETAILED DESCRIPTION OF EMBODIMENTS

In order to clarify the purpose, technical solution, and advantages of the embodiments of the disclosure, the following will provide a clear and complete description of the technical solution in the embodiments of the disclosure in conjunction with the attached drawings. Apparently, the described embodiments are a part of the embodiments of the disclosure, not all of them. The technical features designed in different embodiments of the disclosure described below can be combined with each other as long as they do not conflict with each other. Based on the embodiments in the disclosure, all other embodiments obtained by those skilled in the art without creative labor fall within the scope of protection of the disclosure.

In the description of the disclosure, it should be understood that the terms “center”, “horizontal”, “up”, “down”, “left”, “right”, “vertical”, “horizontal”, “top”, “bottom”, “inside”, and “outside” indicate that the orientation or position relationship is based on the orientation or position relationship shown in the attached drawings, only for the convenience of describing the disclosure and simplifying the description, rather than indicating or implying that the device or component referred to must have a specific orientation, or be constructed and operated in a specific orientation, it cannot be understood as a limitation of the disclosure. In addition, the terms “first” and “second” are only used to describe the purpose and cannot be understood as indicating or implying relative importance or implying the quantity of technical features indicated. Therefore, the features limited to “first” and “second” can explicitly or implicitly include one or more of these features. In the description of the disclosure, unless otherwise specified, “multiple” means two or more. In addition, the term “including” and any variations thereof mean “at least including”.

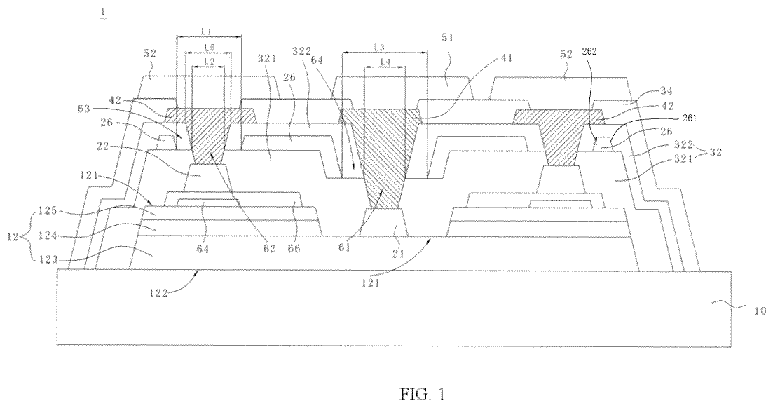

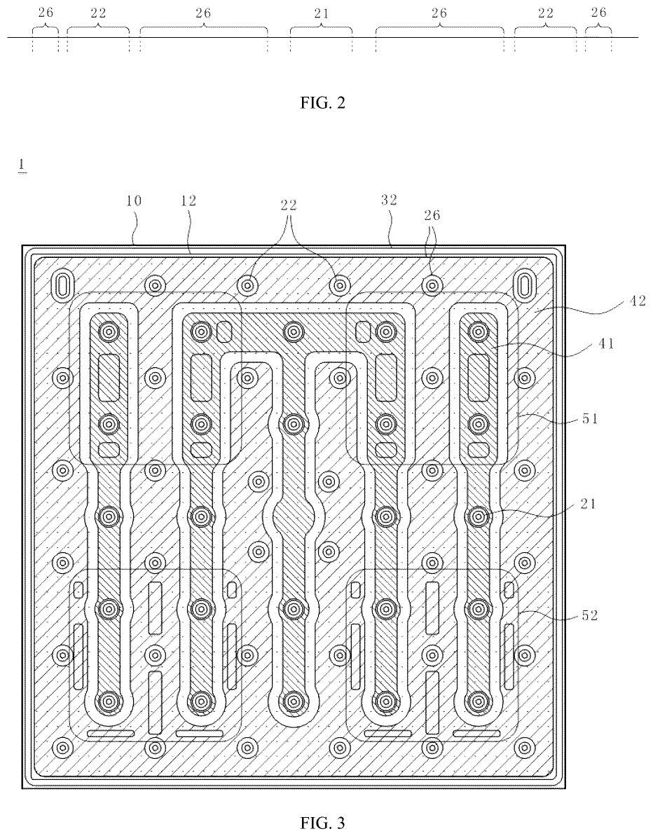

As shown in FIGS. 1 to 3, FIG. 1 illustrates a schematic structural diagram of a light-emitting diode 1 in a first embodiment of the disclosure. FIG. 2 illustrates a schematic diagram of vertical projection line segments of a metal reflective layer 26, a first metal electrode 21, and a second metal electrode 22 illustrated in FIG. 1 on a horizontal plane. FIG. 3 illustrates a schematic structural diagram of a light-emitting diode in the first embodiment of the disclosure. The light-emitting diode 1 includes an epitaxial structure 12, a first metal electrode 21, a second metal electrode 22, an insulating stack layer 32, a metal reflective layer 26, a first connection electrode 41, and a second connection electrode 42.

The epitaxial structure 12 is disposed on a substrate 10. The substrate 10 can be an insulating substrate, and preferably, the substrate 10 can be made of transparent or semi-transparent materials. In an illustrated embodiment, the substrate 10 is a sapphire substrate. In some embodiments, the substrate 10 can be a patterned sapphire substrate, but here is not limited to this. The substrate 10 can also be made of conductive materials or semiconductor materials. For example, the materials of the substrate 10 can include at least one of silicon carbide, silicon, magnesium aluminate, magnesium oxide, lithium aluminate, aluminum gallate, and gallium nitride.

The epitaxial structure 12 includes a lower surface 122 and an upper surface 121 opposite to each other, and the epitaxial structure 12 includes a first semiconductor layer 123, a light-emitting layer 124, and a second semiconductor layer 125 sequentially arranged in that order along a direction from the lower surface 122 to the upper surface 121, that is, the light-emitting layer 124 is disposed between the first semiconductor layer 123 and the second semiconductor layer 125. A portion of an upper surface of the first semiconductor layer is uncovered by the light-emitting layer, thereby forming a mesa or a via. As shown in FIG. 3, the portion of the upper surface of the first semiconductor layer 123 is uncovered by the light-emitting layer 124, thus multiple vias can be formed

The first semiconductor layer 123 can be an N-type semiconductor layer, which can provide electrons to the light-emitting layer 124 under an action of a power source. In some embodiments, the first semiconductor layer 123 includes an N-type doped nitride layer. The N-type doped nitride layer may include one or more N-type impurities of Group IV elements. The N-type impurities can include one or a combination of silicon (Si), germanium (Ge), and stannum (Sn).

The light-emitting layer 124 can be a quantum well structure (QW). In some embodiments, the light-emitting layer 124 can also be a multiple quantum well structure (MQW), which includes multiple quantum well layers (Well) and multiple quantum barrier layers (Barrier) alternately arranged in a repetitive manner, such as GaN/AlGaN, InAlGaN/InAlGaN, or InGaN/AlGaN multiple quantum well structures. Moreover, a composition and a thickness of the well layers within the light-emitting layer 124 determine a wavelength of a generated light.

To enhance a light-emitting efficiency of the light-emitting layer 124, this can be achieved by altering depths of the quantum wells, a number of paired quantum wells and quantum barriers, their thickness, and/or other characteristics within the light-emitting layer 124.

The second semiconductor layer 125 can be a P-type semiconductor layer, which can provide holes to the light-emitting layer 124 under the action of the power source. In some embodiments, the second semiconductor layer 125 includes a P-type doped nitride layer. The P-type doped nitride layer may include one or more P-type impurities of Group II elements. The P-type impurities can include one or a combination of magnesium (Mg), zinc (Zn), and beryllium (Be). The second semiconductor layer 125 can be a single-layer structure or a multi-layer structure with different compositions. Moreover, a configuration of the epitaxial structure 12 is not limited to this and can be selected based on actual requirements for other types of epitaxial structures 12.

The first metal electrode 21 is disposed above the upper surface 121 of the epitaxial structure 12, that is, above the upper surface of the first semiconductor layer 123, and the first metal electrode 21 is electrically connected to the first semiconductor layer 123. The first metal electrode 21 can be a single-layer, double-layer, or multi-layer structure, for example, a stacked structure composed of metal layers such as Cr, Al, Ti, Pt, Au, Ni, etc. In some embodiments, the first metal electrode 21 can be directly formed on a mesa of the epitaxial structure 12, forming a good ohmic contact with the first semiconductor layer 123.

The second metal electrode 22 is disposed above the upper surface 121 of the epitaxial structure 12, that is, above the upper surface of the second semiconductor layer 125, and the second metal electrode 22 is electrically connected to the second semiconductor layer 125. The second metal electrode 22 can be composed of the same material as the first metal electrode 21. Atop view morphology of the light-emitting diode 1 can be as shown in FIG. 3, where the first metal electrode 21 is circular, elliptical, and multiple in number, and the second metal electrode 22 is also circular, elliptical, and multiple in number. A width of each of the first metal electrode 21 and the second metal electrode 22 is in a range of 5 μm to 50 μm, such as 10 μm, 20 μm, 30 μm, etc.

The insulating stack layer 32 is disposed covering a portion of the epitaxial structure 12, a portion of the first metal electrode 22, and a portion of the second metal electrode 32, the insulating stack layer 32 includes a first insulating layer 321 and a second insulating layer 322, and the second insulating layer 322 is disposed above the first insulating layer 321. In other words, the second insulating layer 322 is located above the first insulating layer 321. The insulating stack layer 32 includes a first opening 61 and a second opening 62. The first opening 61 is located above the first metal electrode 21, allowing the first connection electrode 41 to electrically connect with the first metal electrode 21 through the first opening 61. The second opening 62 is located above the second metal electrode 22, allowing the second connection electrode 42 to electrically connect with the second metal electrode 22 through the second opening 62. Both the first opening 61 and the second opening 62 penetrate through the first insulating layer 321 and the second insulating layer 322. The insulating stack layer 32 has different functions depending on a location it covers. For example, when the insulating stack layer 32 covers an inclined sidewall 261 of the epitaxial structure 12, it can prevent an electrical connection between the first semiconductor layer 123 and the second semiconductor layer 125 due to a leakage of conductive materials, reducing the short-circuit anomalies of the light-emitting diode 1, but the disclosed embodiments are not limited to this. A material of the insulating stack layer 32 includes a non-conductive material. The non-conductive material is preferably dielectric materials, which includes electrically insulating materials such as aluminum oxide, silicon nitride, silicon dioxide, titanium oxide, or magnesium fluoride. For example, the insulating stack layer 32 can be silicon dioxide, silicon nitride, titanium oxide, tantalum oxide, niobium oxide, barium titanate, or a combination thereof. The combination, for example, can be a DBR layer formed by the repeated stacking of two materials with different refractive indices. In some embodiments, the first insulating layer 321 is an insulating reflection layer formed by the repeated stacking of two insulating materials. As an example, each sublayer of the DBR layer (first insulating layer 321) has an optical thickness of about 137.5 nm. A thickness of the DBR layer is 2 to 6 μm, with a number of pairs being 10 to 30. More preferably, to ensure a reflectivity of the DBR layer, the number of pairs of the DBR layer is 20 to 30, and the thickness is 4 to 6 μm, for example, the DBR layer has 22 pairs and a thickness of 5 μm.

The metal reflective layer 26 is sandwiched between the first insulating layer 321 and the second insulating layer 322 of the insulating stack layer 32. The metal reflective layer 26 is used to reflect light, thereby allowing more light to be emitted from the light-emitting surface. In some embodiments, a material of the metal reflective layer 26 includes Ag or Al. For example, the metal reflective layer 26 can be an Ag metal reflective layer, an Al metal reflective layer, and so on. In some embodiments, the metal reflective layer 26 forms a reflective structure layer with the first insulating layer 321. The reflective structure layer can be a total reflection layer. For example, the metal reflective layer 26 is an Ag or Al metal reflective layer, and the first insulating layer 321 is an insulating reflection layer (DBR layer) formed by the repeated stacking of silicon dioxide and titanium dioxide. Since the DBR layer does not have a high reflectivity across all wavelength ranges of white light, especially in a longer wavelength range where the reflectivity is relatively low, the Ag or Al metal reflective layer 26 has a high reflectivity in the longer wavelength range. Therefore, the combination of the metal reflective layer and the insulating reflection layer together forms a total reflection layer, which can almost entirely reflect the light back, enhancing the light-emitting performance of the light-emitting diode 1. The first connection electrode 41 is disposed above the insulating stack layer 32 and is connected to the first metal electrode 21. The first connection electrode 41 can serve to expand the current, protect the underlying first metal electrode 21, and provide support and elevation. A material of the first connection electrode 41 can be selected from one or more of Cr, Pt, Au, Ni, Ti, Al. Specifically, a bottom layer metal of the first connection electrode 41 is a Ti metal layer or a Cr metal layer, to ensure a stable adhesion relationship between the first connection electrode 41 and the insulating stack layer 32. Specifically, a surface layer metal of the first connection electrode 41 is a Ti metal layer or a Cr metal layer, to ensure a stable adhesion relationship between the first connection electrode 41 and the adjacent structural layer. The second connection electrode 42 is disposed above the insulating stack layer 32 and is connected to the second metal electrode 22. The second connection electrode 42 can serve to expand the current. The material of the second connection electrode 42 can be selected from one or more of Cr, Pt, Au, Ni, Ti, Al. Preferably, a surface layer metal of the second connection electrode 42 is a Ti metal layer or a Cr metal layer, to ensure a stable adhesion relationship between the second connection electrode 42 and the adjacent structural layer.

In an embodiment, the first opening 61 and the second opening 62 of the insulating stack layer 32 both include a bottom width and a top width, and the bottom width is smaller than the top width. This facilitates a subsequent filling of the first connection electrode 41 and the second connection electrode 42 within the first opening 61 and the second opening 62, respectively, in a continuous and dense manner. Specifically, the top width of the first opening 61 exceeds a width of the upper surface of the first metal electrode 21, and the top width of the second opening 62 exceeds a width of the upper surface of the second metal electrode 22.

The first connection electrode 41 can be in a form of one or more strips, or alternatively, the first connection electrode 41 can be comb-shaped. The second connection electrode 42 is block-shaped. In FIG. 3, the first connection electrode 41 and the second connection electrode 42 are schematically represented with different fill patterns, and the metal reflective layer 26 is also schematically represented with a dotted fill pattern. As shown in FIG. 3, a vertical projection of the first connection electrode 41 is smaller than a vertical projection of the second connection electrode 42. The second connection electrode 42 is arranged around the first connection electrode 41.

As shown in FIG. 2, the vertical projection of at least one of the first metal electrode 21 and the second metal electrode 22 on the horizontal plane is non-overlapped with the vertical projection of the metal reflective layer 26 on the horizontal plane. That is to say, when looking down from a top of the light-emitting diode 1 towards the epitaxial structure 12, at least one of the first metal electrode 21 and the second metal electrode 22 do not intersect or overlap with the metal reflective layer 26. Taking FIG. 2 as an example, within an area of the metal reflective layer 26, there are no first metal electrode 21 and second metal electrode 22. By arranging the vertical projection of at least one of the first metal electrode 21 and the second metal electrode 22 on the horizontal plane not to overlap with the vertical projection of the metal reflective layer 26 on the horizontal plane, when the vertical projection of the at least one of the first metal electrode 21 and the second metal electrode 22 on the horizontal plane are to overlap with the vertical projection of the metal reflective layer 26 on the horizontal plane, it would mean that the at least one of the first opening 61 and the second opening 62 in the insulating stack layer 32 would be very small. In other words, the metal reflective layer 26 would cover above the first metal electrode 21 and the second metal electrode 22. Since the insulating stack layer 32 below the metal reflective layer 26 covers the first metal electrode 21 and the second metal electrode 22, thereby forming a step. A brittleness of the insulating stack layer 32 is prone to cracks at the step. Water vapor can easily infiltrate along these cracks, leading to a migration of the metal reflective layer 26, affecting the stable reflective characteristics of the metal reflective layer 26, and there is a possibility of metal contact between the metal reflective layer 26 and the underlying contact electrode, causing some mixing, thereby affecting its stability. Moreover, it is also susceptible to damage to the metal reflective layer 26 during subsequent etching and other processes.

In an embodiment, the vertical projection of at least one of the lower surface of the first metal electrode and the lower surface of the second metal electrode on the horizontal plane is non-overlapped with the vertical projection of the lower surface of the metal reflective layer on the horizontal plane. In some embodiments, the horizontal plane can be a surface where the lower surface 122 of the epitaxial structure 12 shown in FIG. 1 is located.

In some embodiments, considering the reflective effect of the metal reflective layer 26, a thickness of the metal reflective layer 26 is in a range of 200 nm to 1000 nm, for example, 300 nm to 600 nm, such as 400 nm, for example, 500 nm. A thickness of the second insulating layer 322 is in a range of 200 nm to 1000 nm, for example, 200 nm to 400 nm, or 400 nm to 600 nm.

In some embodiments, the metal reflective layer 26 is located above the upper surface 121 of the epitaxial structure 12 and is not disposed above the substrate 10 that is not covered by the epitaxial structure 12, to ensure that the metal reflective layer 26 is as flat as possible. Specifically, the metal reflective layer 26 is only located directly above the upper surface of the second semiconductor layer 125, so that the formed metal reflective layer 26 is as flat as possible. This prevents a formation of steps and height differences in the metal reflective layer 26 and its underlying structure due to an attachment process, thereby avoiding problems such as water vapor erosion or metal migration, and ensuring the stability of the metal reflective layer 26.

To ensure the reflective effect, in some embodiments, the vertical projection of the metal reflective layer 26 on the upper surface of the second semiconductor layer 125 is overlapped with the vertical projections of the first connection electrode 41 and the second connection electrode 42 on the upper surface of the second semiconductor layer 125. That is to say, the vertical projection of the metal reflective layer 26 on the horizontal plane is overlapped with the vertical projections of the first connection electrode 41 and the second connection electrode 42 on the horizontal plane.

In some embodiments, a vertical projection area of the metal reflective layer 26 on the upper surface of the second semiconductor layer 125 occupies at least 80% of an area of the upper surface of the second semiconductor layer 125. A vertical projection area of the multiple second metal electrodes 22 on the upper surface of the second semiconductor layer 125 occupies less than 20% of the area of the upper surface of the second semiconductor layer 125. Furthermore, a vertical projection area of the current blocking layer 64 below the second metal electrodes 22 on the upper surface of the second semiconductor layer 125 occupies less than 20% of the area of the upper surface of the second semiconductor layer 125.

In some embodiments, the second insulating layer 322 is disposed to cover the upper surface and inclined sidewalls 261 of the metal reflective layer 26. Moreover, the first insulating layer 321 located around the metal reflective layer 26, is in direct contact with the second insulating layer 322. This arrangement ensures that the first insulating layer 321 and the second insulating layer 322 tightly sandwich the metal reflective layer 26, thereby enhancing an overall structural stability. In other words, the first insulating layer 321 is in direct contact with the upper surface of the second insulating layer 322 around the metal reflective layer 26, completely enveloping the metal reflective layer 26.

In some embodiments, as shown in FIG. 1, a minimum horizontal inner spacing L1 of the metal reflective layer 26 at the second opening 62 is greater than a maximum horizontal inner spacing L2 of the first insulating layer 321 at the second opening 62. This ensures that the formed metal reflective layer 26 is as flat as possible, avoiding the formation of steps and height differences in the metal reflective layer 26 and the underlying first insulating layer 321 due to the stepped morphology of the lower layers when the metal reflective layer 26 is deposited. This prevents issues such as water vapor erosion or metal migration. In other words, the metal reflective layer 26 has a third opening 63 surrounding the second opening 62, and a dimension at the bottom of the third opening 63 (i.e., L1) is greater than a dimension of the second opening 62 at the contact position between the first insulating layer 321 and the second insulating layer 322 (i.e., L2).

In a specific embodiment, the minimum horizontal inner spacing L3 of the metal reflective layer 26 at the first opening 61 is greater than the maximum horizontal inner spacing L4 of the first insulating layer 321 at the first opening 61. That is, the metal reflective layer 26 includes a fourth opening 64 surrounding the first opening 61, and a dimension at a bottom of the fourth opening 64 (i.e., L3) is greater than the dimension of the first opening 61 at the contact position between the first insulating layer 321 and the second insulating layer 322 (i.e., L4).

In a specific embodiment, the minimum horizontal inner spacing L1 of the metal reflective layer 26 at the second opening 62 is greater than the maximum horizontal inner spacing L5 of the second insulating layer 322 at the second opening 62. That is, the dimension at the bottom of the third opening 63 (i.e., L1) is greater than the dimension at a top of the second opening 62 (i.e., L5). This ensures that the metal reflective layer 26 is protected and prevents the metal layer 26 from being exposed or damaged by etching. Specifically, the difference between L1 and L5 is at least 6 μm.

The dimensions of each opening mentioned above may include opening diameters or opening widths.

In some embodiment, as shown in FIG. 1, the top of the first opening 61 is higher than the upper surface of the first metal electrode 21, and the top of the second opening 62 is higher than the upper surface of the second metal electrode 22. The heights are calculated with reference to the lower surface 122 of the epitaxial structure 12 as a datum plane.

In an embodiment, based on the design of the metal reflective layer 26 being flatly attached to the first insulating layer 321, further, an edge of the metal reflective layer 26 includes inclined sidewalls 261, upper ends and lower ends of inclined sidewalls are connected to the upper surface and the lower surface of the metal reflective layer 26, respectively. Specifically, a thickness of the second insulating layer 322 is 200 to 1000 nm, and an inclination angle 262 of each inclined sidewall of the metal reflective layer 26 does not exceed 40°, for example, not exceeding 30° or not exceeding 20°. This can prevent, due to the softness of Al and Ag materials, the edge of the metal reflective layer 26 from being lifted on the first insulating layer 321 during a stripping of a photoresist after a negative gel process plating, thereby enhancing the adhesion of its edge. Additionally, it is conducive to the good continuity of the second insulating layer 322 laid above the inclined sidewall of the metal reflective layer 26, avoiding the generation of cracks, thus preventing water vapor erosion, unstable reflectivity, or the creation of leakage current paths, thereby preventing the metal reflective layer 26 from participating in conduction.

In some embodiments, as shown in FIG. 1, the light-emitting diode 1 may also include an insulating structure 34, a first pad electrode 51, and a second pad electrode 52. The insulating structure 34 covers a portion of the insulating stack layer 32, a portion of the first connection electrode 41, and a portion of the second connection electrode 42, primarily serving as an insulating protective layer. The first pad electrode 51 is located above the insulating structure 34 and is connected to the first connection electrode 41. The second pad electrode 52 is located above the insulating structure 34 and is connected to the second connection electrode 42. The first pad electrode 51 and the second pad electrode 52 can be metal pads, which can be formed in the same process using the same material, thus having the same layer structure.

The light-emitting diode 1 further includes a current blocking layer 64 and a transparent current spreading layer 66. The current blocking layer 64 is disposed between the second semiconductor layer 125 and the second metal electrode 22, configured to block current. The transparent current spreading layer 66 is disposed between the current blocking layer 64 and the second metal electrode 22, and the transparent current spreading layer 66 is disposed to cover the current blocking layer 64, configured to spread the current, thereby further enhancing the electrical characteristics of the light-emitting diode 1. Specifically, the vertical projection of the metal reflective layer 26 on the horizontal plane does not overlap with the vertical projection of the current blocking layer 64 on the horizontal plane. A thickness of the current blocking layer 64 is between 100 nm and 400 nm, and a material of the current blocking layer 64 can be silicon dioxide or silicon nitride. A width of the current blocking layer 64 is larger than the width of the second metal electrode 22. Typically, a bottom width of the current blocking layer 64 is greater than a bottom width of the metal reflective layer 26, and is larger by 2 μm to 6 μm. Preferably, the difference between L1 and L5 should be at least 15 μm, which is to avoid overlap between the metal reflective layer 26 and the current blocking layer 64.

The transparent current spreading layer 66 is made of a transparent conductive material, and the transparent conductive material includes indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the embodiment is not limited to the materials.

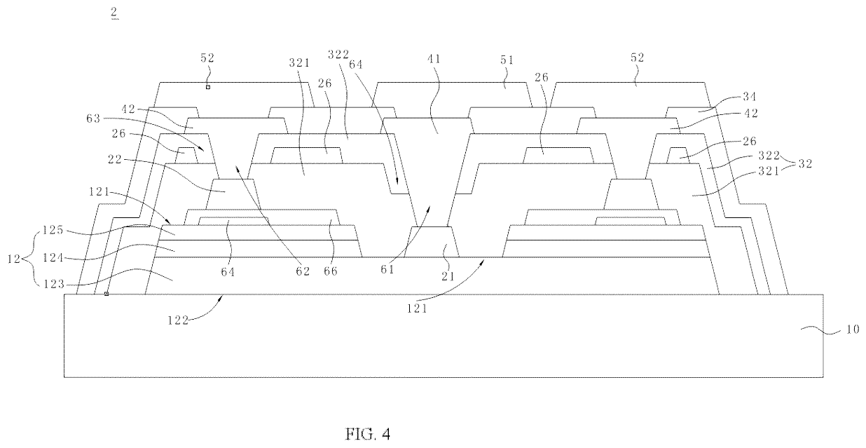

As shown in FIG. 4, FIG. 4 illustrates a structural schematic diagram of the light-emitting diode 2 in a second embodiment of the disclosure. Compared with the light-emitting diode 1 shown in FIG. 1, a main difference of the light-emitting diode 2 in the second embodiment is that: the vertical projection of the metal reflective layer 26 on the horizontal plane only falls within the vertical projection range of the second semiconductor layer 125 on the horizontal plane. That is to say, the metal reflective layer 26 is only disposed directly above the second semiconductor layer 125, so that the formed metal reflective layer 26 is as flat as possible. It will not have poor density due to the step height difference formed by the first insulating layer 321 below it and the second insulating layer 322 covering it when it is attached to the first insulating layer 321, leading to problems such as water vapor erosion or metal migration of the metal reflective layer 26.

In some embodiments, the upper surface 121 of the epitaxial structure 12 located directly below the metal reflective layer 26 is continuously flat, so that the formed metal reflective layer 26 is as flat as possible.

In some embodiments, an additional metal adhesion layer can be disposed between the metal reflective layer 26 and the second insulating layer 322. The metal adhesion layer can be Ti or Cr. A thickness of the metal adhesion layer is 0.1 nm to 20 nm, for example, 0.5 nm to 5 nm.

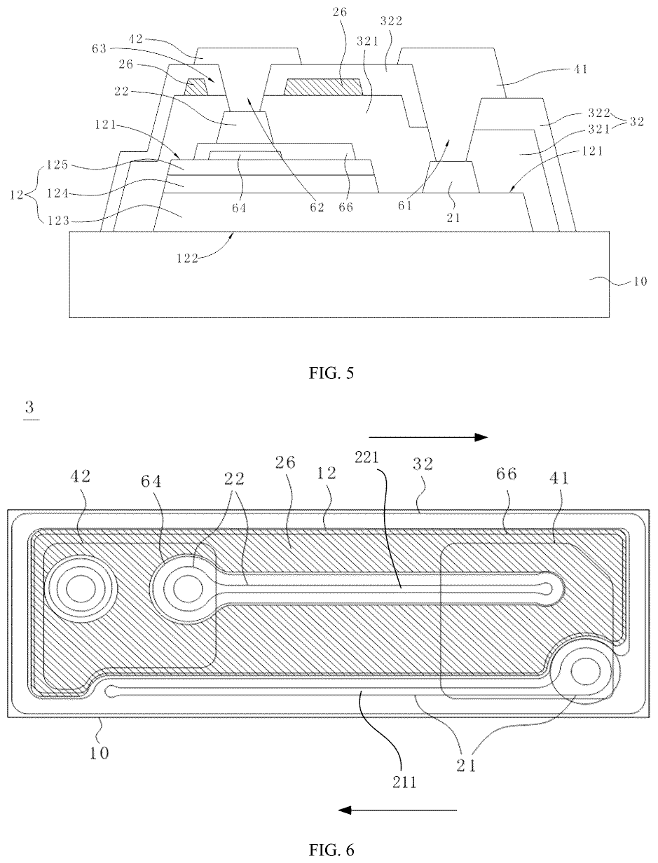

As shown in FIGS. 5 and 6. FIG. 5 illustrates a structural schematic diagram of the light-emitting diode 3 in a third embodiment of the disclosure, and FIG. 6 illustrates a top view of the light-emitting diode 3 in the third embodiment of the disclosure. Compared with the light-emitting diode 1 shown in FIG. 3, a main difference of the light-emitting diode 3 in the third embodiment is that: a top view morphology of the light-emitting diode 3 can be as shown in FIG. 6, where the first metal electrode 21 and the second metal electrode 22 include extended portions 211, 221 to enhance the current spreading performance, and the extended portions can be strip-like. The metal reflective layer 26 in FIG. 6 is represented with a fill pattern. Moreover, the first connection electrode 41 and the second connection electrode 42 can be metal pads, which can be formed in the same process using the same material, thus having the same layer structure.

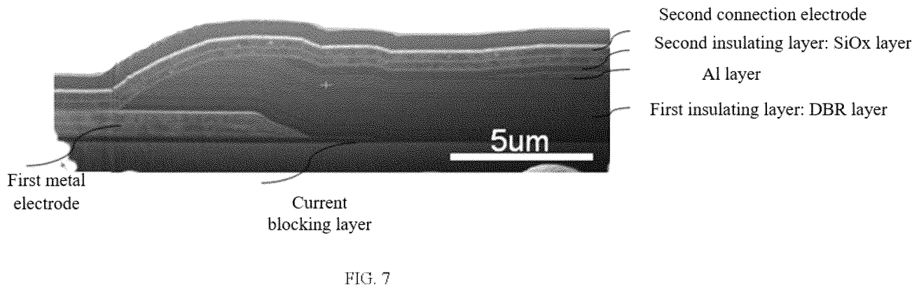

In an embodiment, as shown in FIG. 7, which is a partial structural SEM schematic diagram of the light-emitting diode in the disclosure. The metal reflective layer 26, set between the first insulating layer 321 (this first insulating layer 321 uses a DBR layer) and the second insulating layer 322 (the second insulating layer 322 uses a SiOₓ layer, such as a SiO₂ layer), is an Al layer, and the Al layer avoids the underlying current blocking layer 64. The inclination angle of each inclined sidewall of the Al layer is about 15°, and the second insulating layer 322 attached above the Al layer has good adhesion, with a continuous and dense film layer. It should be noted that the 5 μm in the FIG. 7 is used as a scale for illustration, that is, a length of a white line in FIG. 7 is 5 μm. With the length of 5 μm, a corresponding width or a corresponding thickness of each structural layer in the observed area can be roughly measured.

A light-emitting device utilizing the light emitting diode 1, 2, 3 mentioned in the above embodiments is provided.

In summary, the disclosure provides a light-emitting diode 1, 2, 3 and a light-emitting device. By configuring the insulating stack layer 32 and the metal reflective layer 26, the light emitted from the light-emitting layer 124 is fully reflected, thereby enhancing the light-emitting performance of the light-emitting diodes 1, 2, 3. By arranging the vertical projection of at least one of the first metal electrode 21 and the second metal electrode 22 on the horizontal plane not to overlap with the vertical projection of the metal reflective layer 26 on the horizontal plane, the possibility of damaging the metal reflective layer 26 during processes such as etching is reduced. This prevents the destruction of the reflective characteristics of the metal reflective layer 26, thereby enhancing the reliability and light-emitting performance of the light-emitting diodes 1, 2, 3.

Furthermore, those skilled in the art should understand that, although there are many problems in the related, each embodiment or technical solution of the disclosure may only make improvements in one or a few aspects, and it is not necessary to solve all the technical problems listed in the related art or the background technology at the same time. Those skilled in the art should understand that content not mentioned in a claim should not be considered as a limitation to that claim.

It should be finally stated that: the above embodiments are only used to illustrate the technical solutions of the disclosure, rather than to limit them. Although the disclosure has been described in detail with reference to the foregoing embodiments, those skilled in the art should understand that they can still modify the technical solutions recorded in the foregoing embodiments, or replace part or all of the technical features with their equivalents. These modifications or substitutions do not cause the essence of the corresponding technical solutions to deviate from the scope of the technical solutions of the embodiments of the disclosure.

What is claimed is:

1. A light-emitting diode, comprising:
an epitaxial structure, comprising a lower surface and an upper surface opposite to each other, wherein the epitaxial structure comprises a first semiconductor layer, a light-emitting layer, and a second semiconductor layer sequentially arranged in that order along a direction from the lower surface to the upper surface, and a portion of an upper surface of the first semiconductor layer is uncovered by the light-emitting layer;
a first metal electrode, disposed above the first semiconductor layer of the epitaxial structure and electrically connected to the first semiconductor layer;
a second metal electrode, disposed above the second semiconductor layer of the epitaxial structure and electrically connected to the second semiconductor layer;
an insulating stack layer, disposed covering a portion of the epitaxial structure, a portion of the first metal electrode, and a portion of the second metal electrode, wherein the insulating stack layer comprises a first insulating layer and a second insulating layer, and the second insulating layer is disposed above the first insulating layer;
a metal reflective layer, sandwiched between the first insulating layer and the second insulating layer of the insulating stack layer;
a first connection electrode, disposed above the insulating stack layer and connected to the first metal electrode;
a second connection electrode, disposed above the insulating stack layer and connected to the second metal electrode;
wherein a vertical projection of at least one of the first metal electrode and the second metal electrode on a horizontal plane is non-overlapped with a vertical projection of the metal reflective layer on the horizontal plane.

2. The light-emitting diode as claimed in claim 1, wherein a vertical projection of at least one of a lower surface of the first metal electrode and a lower surface of the second metal electrode on the horizontal plane is non-overlapped with a vertical projection of a lower surface of the metal reflective layer on the horizontal plane.

3. The light-emitting diode as claimed in claim 1, wherein the metal reflective layer and the first insulating layer together form a reflective structure layer.

4. The light-emitting diode as claimed in claim 1, wherein the metal reflective layer is located above the upper surface of the epitaxial structure.

5. The light-emitting diode as claimed in claim 4, wherein the metal reflective layer is only located above the second semiconductor layer.

6. The light-emitting diode as claimed in claim 1, wherein a thickness of the metal reflective layer is in a range of 200 nanometers (nm) to 1000 nm, and a thickness of the second insulating layer is in a range of 200 nm to 1000 nm.

7. The light-emitting diode as claimed in claim 1, wherein a material of the metal reflective layer comprises silver (Ag) or aluminum (Al).

8. The light-emitting diode as claimed in claim 1, wherein the second insulating layer is disposed covering an upper surface and inclined side walls of the metal reflective layer, and the first insulating layer is in direct contact with the second insulating layer at a periphery of the metal reflective layer.

9. The light-emitting diode as claimed in claim 1, wherein the first insulating layer is a distributed bragg reflector (DBR) formed by a repeated stacking of two types of insulating materials, and a thickness of the first insulating layer is in a range of 2 micrometers (μm) to 6 μm.

10. The light-emitting diode as claimed in claim 1, wherein the insulating stack layer comprises a first opening and a second opening, the first opening is located above the first metal electrode, the first opening penetrates through the first insulating layer and the second insulating layer, the second opening is located above the second metal electrode, the second opening penetrates through the first insulating layer and the second insulating layer, the metal reflective layer comprises a third opening surrounding the second opening, and a width at a bottom of the third opening is greater than a width of the second opening at a contact position of the first insulating layer and the second insulating layer.

11. The light-emitting diode as claimed in claim 10, wherein the metal reflective layer comprises a fourth opening surrounding the first opening, and a width at a bottom of the fourth opening is greater than a width of the first opening at the contact position of the first insulating layer and the second insulating layer.

12. The light-emitting diode as claimed in claim 10, wherein a size of the bottom of the third opening is larger than a size of a top of the second opening.

13. The light-emitting diode as claimed in claim 1, further comprising: an insulating structure, a first pad electrode, and a second pad electrode; wherein the insulating structure is disposed covering a portion of the insulating stack layer, a portion of the first connection electrode, and a portion of the second connection electrode; the first pad electrode is located above the insulating structure and connected to the first connection electrode; the second pad electrode is located above the insulating structure and connected to the second connection electrode.

14. The light-emitting diode as claimed in claim 1, further comprising: a current blocking layer and a transparent current spreading layer; wherein the current blocking layer is disposed between the second semiconductor layer and the second metal electrode, the transparent current spreading layer is disposed between the current blocking layer and the second metal electrode, and the transparent current spreading layer is arranged covering the current blocking layer.

15. The light-emitting diode as claimed in claim 14, wherein the vertical projection of the metal reflective layer on the horizontal plane is non-overlapped with a vertical projection of the current blocking layer on the horizontal plane.

16. The light-emitting diode as claimed in claim 1, wherein the vertical projection of the metal reflective layer on the horizontal plane is overlapped with both vertical projections of the first connection electrode and the second connection electrode on the horizontal plane.

17. The light-emitting diode as claimed in claim 1, wherein an edge of the metal reflective layer comprises inclined sidewalls, and inclination angles of the respective inclined sidewalls are less than or equal to 40°.

18. The light-emitting diode as claimed in claim 1, wherein each of the first metal electrode and the second metal electrode comprise a strip-shaped extension, and the strip-shaped extension extends in a direction of a connecting line of the first connection electrode with the second connection electrode.

19. The light-emitting diode as claimed in claim 1, wherein portions of the vertical projection of the metal reflective layer are arranged spaced from one another and just above the second semiconductor layer.

20. A light-emitting device, comprising the light-emitting diode as claimed in claim 1.
